(19) United States
(12) Patent Application Publication
(10) Pub. No.: US 2018/0308752 A1
(43) Pub. Date: Oct. 25, 2018

(54) MIDDLE-OF-LINE LOCAL INTERCONNECT STRUCTURES WITH HYBRID FEATURES

(71) Applicant: GLOBALFOUNDRIES Inc., Grand Cayman (KY)

(72) Inventors: Xunyuan Zhang, Troy, NY (US); Frank W. Mont, Troy, NY (US); Sean X. Lin, Watervliet, NY (US); Mark V. Raymond, Latham, NY (US)

(21) Appl. No.: 15/494,762

(22) Filed: Apr. 24, 2017

(51) Int. Cl. H01L 21/768; H01L 23/532; H01L 23/535; H01L 23/528

(52) U.S. Cl. CPC H01L 21/76895; H01L 23/53242; H01L 23/53209; H01L 23/535; H01L 21/76816; H01L 21/76883; H01L 21/76843; H01L 21/7684; H01L 23/5283

(57) ABSTRACT

Interconnect structures and methods of forming interconnect structures. An opening is formed that penetrates from a top surface of a dielectric layer into the dielectric layer. A first conductor layer is conformally deposited with a uniform thickness on the dielectric layer surrounding the first opening. A second conductor layer is formed in a space inside the first opening that is interior of the first conductor layer. The first conductor layer and the second conductor layer collectively define a hybrid feature that is embedded in the dielectric layer.

### BACKGROUND

The present invention relates to integrated circuits and semiconductor device fabrication and, more specifically, to local interconnect structures and methods of forming local interconnect structures.

An interconnect structure may be used to electrically connect device structures fabricated by front-end-of-line (FEOL) processing on a substrate. A back-end-of-line (BEOL) portion of the interconnect structure may be fabricated using a damascene process in which via openings and trenches etched in a dielectric layer are filled with a metal, such as copper or aluminum, to create a metallization level. The lowest or first metal level of the BEOL interconnect structure may be coupled with the device structures by features of a local interconnect structure fabricated by middle-of-line (MOL) processing.

Features of the MOL local interconnect structure may be formed in openings defined in a dielectric layer overlying the device structures. Tungsten is a common material that is used by MOL processing to form the features of the local interconnect structure. However, with scaling of local interconnect features, the electrical resistance of tungsten may prove to be unacceptably high.

Improved local interconnect structures and methods of forming local interconnect structures are needed.

### SUMMARY

According to an embodiment of the invention, a structure includes a dielectric layer with a top surface and a first opening that penetrates from the top surface of the dielectric layer into the dielectric layer. A feature is located inside the opening. The feature includes a first conductor layer on the dielectric layer surrounding the first opening and a second conductor layer on the first conductor layer. The first conductor layer has a conformal thickness, and the second conductor layer is located in a space inside the first opening that is interior of the first conductor layer.

According to an embodiment of the invention, a method includes forming an opening in a dielectric layer that penetrates from a top surface of the dielectric layer into the dielectric layer, conformally depositing a first conductor layer with a uniform thickness on the dielectric layer surrounding the first opening, and forming a second conductor layer in a space inside the first opening that is interior of the first conductor layer. The first conductor layer and the second conductor layer collectively define a hybrid feature that is embedded in the dielectric layer.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-4 are cross-sectional views of a structure at successive fabrication stages of a processing method in accordance with an embodiment of the invention.

### DETAILED DESCRIPTION

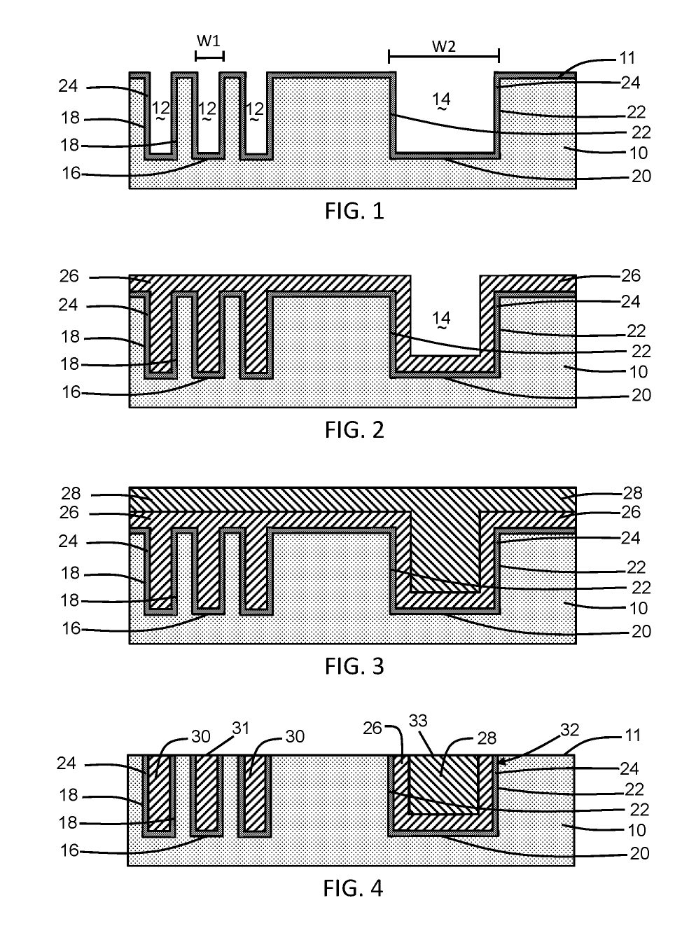

With reference to FIG. 1 and in accordance with an embodiment of the invention, a dielectric layer 10 may be processed by middle-of-line (MOL) processing to form a metallization level of a local interconnect structure. The dielectric layer 10 may be composed of an electrical insulator, such as silicon dioxide (SiO₂), silicon nitride (Si₃N₄), or another suitable dielectric material. The dielectric layer 10 is located on a substrate previously processed by front-end-of-line (FEOL) processing to form device structures, such as field-effect transistors. Additional metallization levels (not shown) of a back-end-of-line (BEOL) interconnect structure may be formed above the metallization level that includes dielectric layer 10.

Openings 12, 14 in the dielectric layer 10 penetrate from a top surface 11 of the dielectric layer 10 to a given depth into the dielectric layer 10. The openings 12, 14 may be formed by photolithography and etching at selected locations distributed across the surface area of dielectric layer 10. Specifically, a photoresist layer may be applied, exposed to a pattern of radiation projected through a photomask, and developed to form a corresponding pattern of openings situated at the intended locations for the openings 12, 14. The patterned photoresist layer is used as an etch mask for an etching process, such as a reactive ion etching (RIE), that removes portions of the dielectric layer 10 to form the openings 12, 14.

Each of the openings 12 includes a base 16 and at least one sidewall 18 that extends from the top surface 11 of the dielectric layer 10 through the dielectric layer 10 to the base 16. The openings 12 in the dielectric layer 10 may be, for example, contact openings defined in the dielectric layer 10, and may have an aspect ratio of depth to width that is characteristic of a contact opening. The openings 12 may open onto an underlying feature (not shown) of a FEOL device structure, such as the source, drain, or gate electrode of a field-effect transistor.

The opening 14 includes a base 20 and at least one sidewall 22 that extends from the top surface 11 of the dielectric layer 10 through the dielectric layer 10 to the base 20. The opening 14 in the dielectric layer 10 may be, for example, a trench defined in the dielectric layer 10, and may have an aspect ratio of depth to width that is characteristic of a trench. The opening 14 may be used to form, for example, a contact of larger dimensions than the contacts formed using openings 12, or a non-functional metal structure such as a crackstop, an alignment mark, etc., that is not connected with an underlying feature of a FEOL device structure.

The base 16 of the openings 12 and the base 20 of the opening 14 may be located at the same given depth in the dielectric layer 10. The openings 12 have at least one lateral dimension, for example width W1. The opening 14 has at least one lateral dimension, for example width W2. The lateral dimension of each opening 12 is smaller than the lateral dimension of the opening 14. For example, the lateral dimension of each opening 12 may be less than 60 nanometers wide, and the lateral dimension of the opening 14 may be greater than 60 nanometers wide. As a result, the openings 12 are characterized by a higher aspect ratio of depth to width than the opening 14.

A barrier/liner layer 24 of a given thickness is deposited on the dielectric layer 10 at the base 16 and the at least one sidewall 18 of each opening 12 and at the base 20 and the at least one sidewall 22 of the opening 14, and is also deposited on the top surface 11 of the dielectric layer 10 in the field area. The barrier/liner layer 24 may be comprised of titanium (Ti), titanium nitride (TiN), tantalum (Ta), tantalum nitride (TaN), or a multilayer combination of these materials (e.g., a TiN/Ti bilayer) conformally deposited with a uniform thickness by chemical vapor deposition (CVD) or atomic layer deposition (ALD).

With reference to FIG. 2 in which like reference numerals refer to like features in FIG. 1 and at a subsequent fabrication stage, a conductor layer 26 is formed that completely fills the space inside each of the openings 12 interior of the barrier/liner layer 24. The conductor layer 26 also that partially fills the opening 14 as a conformal film formed on the barrier/liner layer 24. In that regard, the conductor layer 26 conforms to the shape of the opening 14 such that the dielectric layer 10 bordering each sidewall 18 and the base 16 of the opening 14 are completely covered with a uniformly thick layer of the deposited conductor. The deposited thickness of the conductor layer 26 is controlled such that the opening 14 is only partially filled and not completely filled by conductor from the conductor layer 26. The conductor layer 26 may be composed of a metal, such as ruthenium (Ru), formed using a volatile metal precursor of ruthenium deposited by low-temperature chemical vapor deposition (CVD) or atomic layer deposition (ALD).

With reference to FIG. 3 in which like reference numerals refer to like features in FIG. 2 and at a subsequent fabrication stage, a conductor layer 28 may be formed that fills the open space inside the opening 14 that is interior of the conductor layer 26 and the barrier/liner layer 24. The conductor layer 28 also forms an overburden on the field area on the top surface 11 of the dielectric layer 10 to ensure complete filling of the opening 14. The conductor layer 28 is composed of a different metal than the conductor layer 26. In an embodiment, the conductor layer 28 may be composed of cobalt (Co) deposited by PVD with, for example, a sputtering process, or deposited by electroplating. The openings 12 are filled by portions of the conductor from the conductor layer 26 prior to the deposition of conductor layer 28, which block additional filling during the deposition conductor layer 28. As a result, the openings 12 are completely filled by portions of the conductor from the conductor layer 26 and are not filled even partially by conductor from the conductor layer 28, which means that the openings 12 are free of the conductor from the conductor layer 28.

The resulting structure may be annealed, e.g., thermally annealed, following the deposition of the conductor layer 28. In an embodiment, the resulting structure may be thermally annealed in a reducing ambient (e.g., hydrogen (H₂)) at a substrate temperature of 300° C. to 400° C. The thermal anneal may be effective, among other effects, to drive impurities out of the conductor layers 26, 28 and to also increase the grain size of the polycrystalline material of conductor layers 26, 28 so as to reduce their electrical resistance.

With reference to FIG. 4 in which like reference numerals refer to like features in FIG. 3 and at a subsequent fabrication stage, portions of the conductor layer 28 and the conductor layer 26 in the field area on the top surface 11 of the dielectric layer 10 are removed. In an embodiment, the removal may be accomplished by a planarization technique, such as a chemical mechanical polishing (CMP) process. The barrier/liner layer 24 in the field area on the top surface of dielectric layer 10 is subsequently removed by planarization, such as with another CMP process. Material removal during each CMP process may combine abrasion and an etching effect that polishes the targeted material. Each CMP process may be conducted with a commercial tool using a polishing pad and slurries selected to polish the targeted material.

In an embodiment, the same slurry and polishing procedure may be used to remove, without interruption to change the composition of the slurry, the conductor layer 28 in the field area on the top surface of dielectric layer 10 and the conductor layer 26 in the field area on the top surface of dielectric layer 10. For example, a single slurry may be used to remove, without interruption to change the composition of the slurry, ruthenium constituting conductor layer 26 and cobalt constituting conductor layer 28.

Features 30, which are located inside the openings 12 (FIG. 1), represent the remaining portions of the conductor layer 26 located inside the openings 12 and are embedded in the dielectric layer 10. A hybrid feature 32, which is resident inside the opening 14 (FIG. 1) and also embedded in the dielectric layer 10, includes an inner portion constituted by the conductor originating from the conductor layer 26 and an outer portion constituted by the conductor originating from the conductor layer 28. The inner portion of the conductor layer 28 occupies a central position inside an outer perimeter that is occupied by the outer portion of the conductor layer 26. The conductor layer 26 is interposed between the inner portion of the conductor layer 28 and the barrier/liner layer 24 coating the dielectric layer 10 surrounding the opening 14. The inner portion of conductor layer 28 defines a core of the hybrid feature 32 and the portion of the conductor layer 26 defines a three-sided tub in which the feature core is situated. The respective top surfaces 31 of the features 30 and the top surface 33 of the hybrid feature 32 are coplanar with the top surface 11 of the dielectric layer 10 after planarization.

The features 30 are composed in their entirety from the material of the conductor layer 26, which may be a replacement material for tungsten that is conventionally used in middle-of-line (MOL) processes for forming features. In comparison to other candidate replacement materials, the material of the conductor layer 26 may have an enhanced resistance to etching processes forming overlying openings for features that intersect the top surfaces of the features. In particular, features 30 that are composed of ruthenium may have an enhanced resistance to such etching processes in comparison with cobalt, which is another candidate replacement material for tungsten.

While the features 30 are composed in their entirety from the material from the conductor layer 26, the hybrid feature 32 is partially composed of the material from the conductor layer 26 and partially composed of the material from conductor layer 28. This combination may be of relevance when filling larger-sized features if the material of the conductor layer 26 is more costly as a raw material than the material of the conductor layer 28. The features 30 may receive the benefit of the enhanced resistance to etching processes while minimizing the cost because, after its formation, the hybrid feature 32 may not be exposed to the same etching processes and may not require the same level of etching resistance as the features 30.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a dielectric layer including a top surface, a first opening that penetrates from the top surface of the dielectric layer into the dielectric layer, and a second opening that penetrates from the top surface of the dielectric layer into the dielectric layer;
a barrier/liner layer including a first portion on the dielectric layer surrounding the first opening and a second portion on the dielectric layer surrounding the second opening;
a first feature inside the first opening, the first feature including a first conductor layer on the first portion of the barrier/liner layer and a second conductor layer on the first conductor layer, the first conductor layer having a conformal thickness, and the second conductor layer located in a space inside the first opening that is interior of the first conductor layer; and
a second feature inside the second opening, the second feature including a conductor from the first conductor layer that is arranged to completely fill a space inside the second opening that is interior of the second portion of the barrier/liner layer.

2-3. (canceled)

4. The structure of claim 1 wherein the first opening has a first aspect ratio, and the second opening has a second aspect ratio that is less than the first aspect ratio.

5. The structure of claim 1 wherein the second feature is a contact, and the second opening is a contact opening.

6-7. (canceled)

8. The structure of claim 1 wherein the conductor of the first conductor layer is ruthenium, and the second conductor layer is comprised of cobalt.

9. The structure of claim 1 wherein the first feature is a contact, and the first opening is a contact opening.

10. The structure of claim 1 wherein the first feature is a non-functional feature.

11. A method comprising:
forming a first opening and a second opening in a dielectric layer that penetrates from a top surface of the dielectric layer into the dielectric layer;
depositing a barrier/liner layer that includes a first portion on the dielectric layer surrounding the first opening and a second portion on the dielectric layer surrounding the second opening
conformally depositing a first conductor layer with a uniform thickness on the first portion of the barrier/liner layer and the second portion of the barrier/liner layer; and
forming a second conductor layer in a space inside the first opening that is interior of the first conductor layer,
wherein the first conductor layer and the second conductor layer collectively define a first feature, and the first conductor layer defines a second feature that completely fills the space inside the second opening that is interior of the second portion of the barrier/liner layer.

12. The method of claim 11 further comprising:
after the second conductor layer is formed, heating the first conductor layer and the second conductor layer with a thermal annealing process.

13. (canceled)

14. The method of claim 11 wherein the first opening has a first aspect ratio, and the second opening has a second aspect ratio that is less than the first aspect ratio.

15-16. (canceled)

17. The method of claim 11 wherein the first conductor layer and the second conductor layer form on the top surface of the dielectric layer, and further comprising:
removing the first conductor layer and the second conductor layer from the top surface of the dielectric layer with a single slurry in a chemical mechanical polishing process.

18. The method of claim 11 wherein the first conductor layer is comprised of ruthenium, and the second conductor layer is comprised of cobalt.

19. The method of claim 11 wherein the first feature is a contact, and the first opening is a contact opening.

20. The method of claim 11 wherein the first feature is a non-functional feature.
